(19) United States
(12) Patent Application Publication
(10) Pub. No.: US 2011/0222214 A1
(43) Pub. Date: Sep. 15, 2011

(54) HOUSING OF AN ELECTRONIC DEVICE AND METHOD FOR MAKING SAME

(75) Inventors: TONG-MING LAN, Shenzhen (CN); GUO-YONG LI, Shenzhen (CN); PO-FENG HO, Shindian (TW); QIU-JIANG XU, Shenzhen (CN); GUO-JIANG FANG, Shenzhen City (CN)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/904,239

(22) Filed: Oct. 14, 2010

(30) Foreign Application Priority Data
Mar. 12, 2010 (CN) 201010123075.0

(51) Int. Cl. H05K 5/00; B29C 45/14

(52) U.S. Cl. 361/679.01; 264/251

(57) ABSTRACT

A housing of the electronic device includes a transparent window frame, a first housing unit, and a second housing unit. The window frame has a internal surface and a peripheral wall; The first housing unit integrally joins to the peripheral wall of the window frame by injection molding; The second housing unit integrally joins to the internal surface of the window frame to form a window area, the second housing unit integrally joins to the internal surface of the first housing unit.

### BACKGROUND

1. Technical Field

The present disclosure relates to a housing of an electronic device and a method for making the housing.

2. Description of Related Art

Housing of an electronic device can be fabricated by injection molding. An insert is placed into a mold, a plastic material is injected into the mold and interlocks the insert to form the housing. However, the strength of the combination of the insert with the hardened plastic material can not always be maintained.

Therefore, there is room for improvement within the art.

### BRIEF DESCRIPTION OF THE DRAWINGS

Many aspects of the present housing of an electronic device and method for making the same can be better understood with reference to the following drawings. The components in the various drawings are not necessarily drawn to scale, the emphasis instead being placed upon clearly illustrating the principles of the present disclosure. Moreover, in the drawings, like reference numerals designate corresponding parts throughout the diagrams.

FIG. 1 is a schematic view of a housing of an electronic device according to an exemplary embodiment.

FIG. 2 is a cross-sectional schematic view of the housing shown in FIG. 1.

FIG. 3 is a cross-sectional schematic view of a mold for molding the housing shown in FIG. 1.

### DETAILED DESCRIPTION

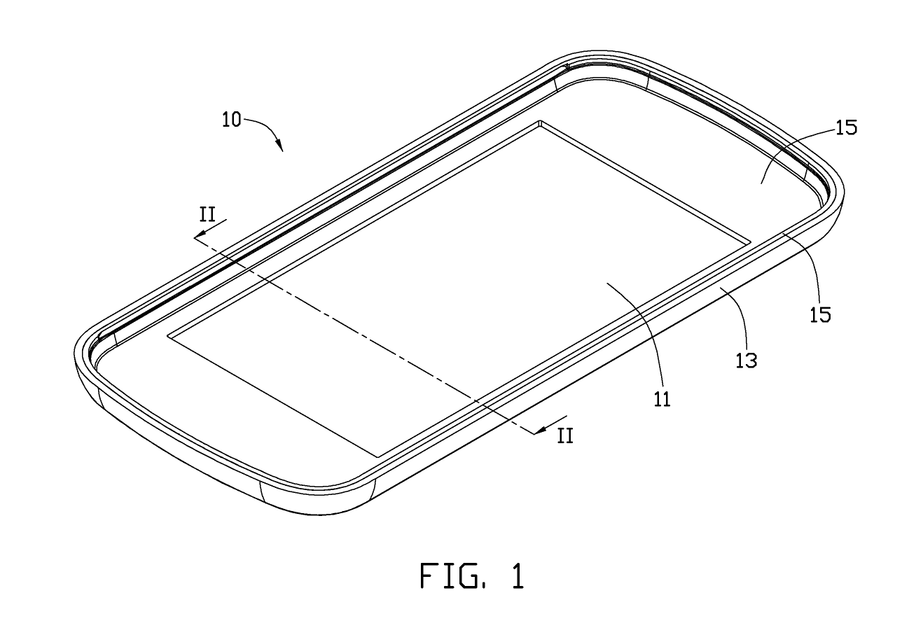

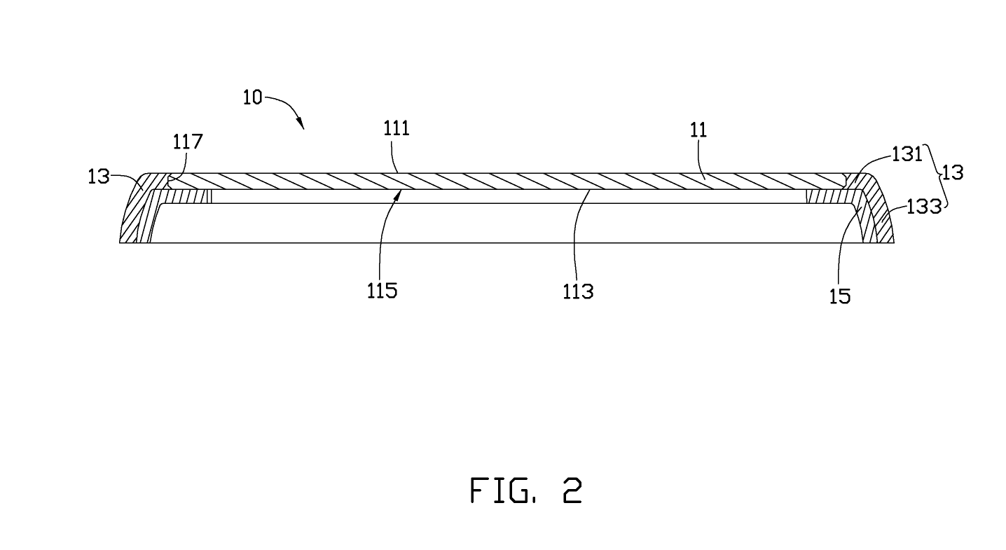

FIGS. 1 and 2 show a housing 10 of an electronic device, such as a mobile phone or a personal digital assistant. The housing 10 includes a window frame 11, a first housing unit 13 connecting and surrounding the window frame 11, and a second housing unit 15 connecting the window frame 11 and the first housing unit 13.

The window frame 11 can be a transparent rectangular glass panel, and includes an external surface 111, an internal surface 113 and a peripheral wall 117. The internal surface 113 has a window area 115. The peripheral wall 117 forms an arcuate surface for interlocking with the first housing unit 13. A thickness of the window frame 11 can be in the range of about 1 mm (millimeter) to about 1.25 mm. The pencil hardness of the window frame 11 may be 6 H (Hardness). The Young's Modulus can be in the range of about 70-75 GPa. The shear modulus can be in the range of about 30-35 GPa. The light transmittance of the window frame 11 can be over 90 percent.

The first housing unit 13 forms at the periphery of the window frame 11 and can be joined to the window frame 11 by injection molding. The first housing unit 13 includes a first section 131, and a second section 133 connected to the first section 131. The first section 131 interlocks with to the window frame 11 and is coplanar with the window frame 11. The first section 131 has substantially the same thickness as the window frame 11. Corresponding to the arcuate surface of the peripheral wall 117, the first section 131 forms an arcuate interlocking surface (not labeled) for increasing the interlocking strength of the window frame 11 and the first housing unit 13. The first housing unit 13 can be transparent or translucent, and may be made of one or more impact resistant and wear resistant plastic material selected from a group including polycarbonate (PC), Polymethyl Methacrylate (PMMA), and Polyamide (PA).

The second housing unit 15 has the similar structure as the first housing unit 13, the second housing unit 15 overlies on the internal surface 113 of the window frame 11 (except for in the window area 115) and the internal surface (not labeled) of the first housing unit 13. The second housing unit 15 can be joined to the first housing unit 13 and the window frame 11 by injection molding. The second housing unit 15 may be made of a mixture of material selected from a group including the mixture of PC with glass fiber, a mixture of PA with glass fibers, or a mixture of PC, Acrylonitrile Butadiene Styrene (ABS) with glass fibers. All of the mixture materials contain glass fiber weighted about 30% or greater than 30% for greatly decreasing the shrinkage of the mixture material and accordingly greatly increase the combining strength of the second housing unit 15 and the window frame 11. The second housing unit 15 can be printed with colorful patterns on the surface adjoining the first housing unit 13 and the window frame 11. Accordingly, the colorful patterns can be viewed through the window frame 11 and the first housing unit 13. Understandably, the patterns can be printed on a transparent film, the film abutting the second housing unit 15 to combine the window frame 11 and the first housing unit 13. The second housing unit 15 has a strong combining force with the window frame 11 and the first housing unit 11. For example, the interlocking force may be more than 400 N exceeding the commonly acceptable interlocking strength reach 250 N.

The fabrication of the housing 10 may include at least the following steps.

A window frame 11 is provided in the form of a transparent glass panel, and includes the external surface 111, the internal surface 113 and the peripheral wall 117. The internal surface 113 has the window area 115.

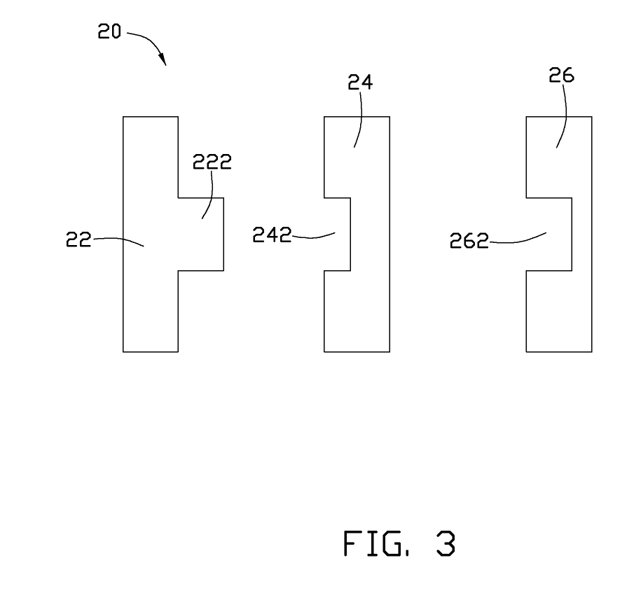

Referring to FIG. 3, a molding assembly 20 is provided and includes a male mold 22, a first female mold 24 and a second female mold 26. The male mold 22 forms a core 222, the first female mold 24 has a first cavity 242 engageable with the core 222 to form a first chamber (not shown). The second female mold 26 has a second cavity 262 deeper than the first cavity 242 and engageable with the core 222 to form a second chamber (not shown).

The window frame 11 is placed into the first cavity 242 of the female mold 24.

Then, the male mold 22 engages with the first female mold 24, and a first plastic material is injected into the first chamber to fill the first chamber. The first plastic material interlocks with the window frame 11 and forms the first housing unit 13. The first plastic material can be selected from a group including polycarbonate (PC), Polymethyl Methacrylate (PMMA), and Polyamide (PA).

The male mold 22 disengages from the first female mold 24, and the first housing unit 13 integrally connecting the window frame 11 attached on the core 222. At the moment, patterns can be printed on the internal surface of the window frame 11 except for the window area 115. Understandably, it can be a decorative film having patterns to overly the internal surface of the window frame 11 except for the window area 115. If needed, the bond with adhesive (not shown) can be placed on the internal surface of the window frame 11 except for the window area 115.

The male mold 22 engages with the second female mold 26. The core 222 carrying the window frame 11 and the first housing member 13 extends into the second cavity 262 to enclose the second chamber. A second plastic material is injected into the second chamber, and the second plastic material interlocks with the internal surface of the window frame 11 (except for the window area 115) and internal surface of the first housing unit 13 to form the housing 10. The second plastic material forms the second housing unit 15. The second plastic material may be made of any of the mixtures previously mentioned.

The male mold 22 disengages from the second female mold 26 to allow extraction of the molded housing 10.

It is to be understood that even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A housing of an electronic device, comprising:
a transparent window frame having a internal surface and a peripheral wall;
a first housing unit integrally joined to the window frame by injection molding; and
a second housing unit integrally joined to the window frame and the first housing unit by injection molding; wherein:
the first housing unit interlocks with the peripheral wall of the window frame and surrounds the window frame, the second housing unit interlocks with the internal surface of the window frame to form a window area, additionally, the second housing unit interlocks with the internal surface of the first housing unit.

2. The housing of an electronic device as claimed in claim 1, wherein the peripheral wall forms an arcuate surface to interlock with the first housing unit.

3. The housing of an electronic device as claimed in claim 1, wherein the thickness of the window frame is in the range of about 1 to about 1.25 mm.

4. The housing of an electronic device as claimed in claim 1, wherein the pencil hardness of the window frame reaches to 6 H, the Young's Modulus of the window frame is in the range of about 70-75 GPa, the shear modulus of the window frame is in the range of about 30-35 GPa.

5. The housing of an electronic device as claimed in claim 1, wherein the transmittance of the window frame is over 90 percent.

6. The housing of an electronic device as claimed in claim 1, wherein the first housing unit includes a first section, and a second section bended connecting to the first section, the first section interlocks with the window frame and is coplanar with the window frame.

7. The housing of an electronic device as claimed in claim 1, wherein the first housing unit is made of a plastic material selected from a group including polycarbonate (PC), Polymethyl Methacrylate (PMMA), and Polyamide (PA).

8. The housing of an electronic device as claimed in claim 1, wherein the second housing unit is made of a mixture selected from a group including the mixture of PC with glass fiber, a mixture of PA with glass fiber, or a mixture of PC, Acrylonitrile Butadiene Styrene (ABS) with glass fiber.

9. The housing of an electronic device as claimed in claim 8, wherein the weight percent of glass fiber is equal or greater than 30% in the corresponding mixture.

10. The housing of an electronic device as claimed in claim 1, wherein the second housing unit has a interlocking force with the window frame and the first housing unit, the interlocking force is beyond 400 N.

11. A method for making a housing of an electronic device, comprising:
providing a transparent window frame including a internal surface and a peripheral wall;
providing a molding assembly including a male mold, a first female mold, and a second female mold, the first female mold and the second female mold respectively engageable with the male to form a first chamber and a second chamber;
placing the window frame into the first chamber and injecting a first plastic material into the first chamber, the first plastic material interlocking with the peripheral wall of the window frame and the plastic material forming a first housing unit;
disengaging the male mold from the first female mold, and engaging the male mold with the second female mold, making the first housing unit and the window frame being in the second chamber;
injecting a second plastic material into the second chamber, the second plastic material partly interlocking with the internal surface of the window frame to form a window area, and the second material interlocking with the internal surface of the first housing unit, the second plastic material forming a second housing unit;
disengaging the male mold from the second female mold and taking a housing out.

12. The method for making the housing of an electronic device as claimed in claim 11, further including a step to place a decorative film having patterns on the internal surface of the window frame except for the window area before the male mold engaging with the second female mold.

13. The method for making the housing of an electronic device as claimed in claim 11, further including a step to print patterns on the internal surface of the window frame except for the window area before the male mold engaging with the second female mold.

14. The method for making the housing of an electronic device as claimed in claim 11, wherein the first plastic material is selected from a group including polycarbonate (PC), Polymethyl Methacrylate (PMMA), and Polyamide (PA).

15. The method for making the housing of an electronic device as claimed in claim 11, wherein the second plastic material is a mixture selected from a group including the mixture of PC with glass fiber, a mixture of PA with glass fiber, or a mixture of PC, Acrylonitrile Butadiene Styrene (ABS) with glass fiber.

16. The method for making the housing of an electronic device as claimed in claim 11, wherein the window frame is a glass, the pencil hardness of the window frame reaches to 6 H, the Young's Modulus of the window frame is in the range of about 70-75 GPa, the shear modulus of the window frame is in the range of about 30-35 GPa.
